(19) United States
(12) Patent Application Publication
(10) Pub. No.: US 2021/0246556 A1
(43) Pub. Date: Aug. 12, 2021

(54) REACTOR SYSTEM WITH MULTI-DIRECTIONAL REACTION CHAMBER

(71) Applicant: ASM IP Holding B.V., Almere (NL)

(72) Inventor: Yukihiro Mori, Tokyo (JP)

(21) Appl. No.: 17/169,440

(22) Filed: Feb. 6, 2021

Related U.S. Application Data
(60) Provisional application No. 62/975,584, filed on Feb. 12, 2020.

(51) Int. Cl. C23C 16/54; C23C 16/44; C23C 16/455

(52) U.S. Cl. CPC C23C 16/54; C23C 16/45544; C23C 16/4408

(57) ABSTRACT

A reactor system may comprise a plurality of reaction chambers; a plurality of transfer chambers; and/or at least two gate valves coupled to each reaction chamber of the plurality of reaction chambers. A first gate valve of the at least two gate valves may fluidly couple a first respective reaction chamber of the plurality of reaction chambers to a first transfer chamber of the plurality of transfer chambers, and a second gate valve of the at least two gate valves may fluidly couple the first respective reaction chamber to a second transfer chamber of the plurality of transfer chambers. In various embodiments, each of the plurality of transfer chambers may comprise a transfer tool, wherein each transfer tool may be configured to transfer a substrate into and/or out of multiple reaction chambers.

### FIELD OF THE DISCLOSURE

The present disclosure generally relates to a reactor system, particularly to a reactor system comprising one or more multi-directional reaction chambers.

### BACKGROUND

Reactor systems may comprise various configurations of reaction chambers, substrate transfer chambers (TC), load lock chambers (LLC), and/or similar chambers or modules for processing substrates, for example. With reference to reaction chamber configuration 90, shown in FIG. 2, a number of reaction chambers 60 may be disposed around and/or coupled to a TC 80 comprising a transfer tool 85 for transferring substrates between reaction chambers 60. In another embodiment of a reactor system 91, shown in FIG. 3, a number of reaction chambers 61 may surround and/or be coupled to one or more TCs (e.g., TCs 81 and 82). Each TC may comprise one or more transfer tools (e.g., transfer tool 86 comprised in TC 81 and transfer tool 87 comprised in TC 82). Such embodiments of reactor systems may comprise reaction chambers having one gate configured to allow transfer of a substrate(s) in and out of the respective reaction chamber (e.g., a gate which fluidly couples the respective reaction chamber with a TC and/or an LLC, such as LLC 70 or 71).

The transfer tools in a reactor system may be configured to transfer substrates between chambers (e.g., between reaction chambers) to begin or during a processing method. For example, a substrate may be transferred between different reaction chambers in a reactor system for different steps within a substrate processing method (e.g., to create a semiconductor). However, if a transfer tool is required to complete two or three (or more) substrate transfers between reaction chambers in a limited amount of time as required by a substrate processing method, the transfer tool may not be able to keep up with the required substrate transfers in the required time. In other words, with too many required substrate transfers between reaction chambers in a reactor system during a processing method, there may be a substrate “traffic jam,” causing delays in substrate transfers between reaction chambers relative to the desired timing of such substrate transfers and subsequent processing step(s). Therefore, a substrate in a certain reaction chamber of a reactor system (such as reactor system 90 or 91) may be required to remain in a reaction chamber after the process step in such a reaction chamber is complete, before being transferred to another reaction chamber. Such waiting may decrease the efficiency of a reactor system to produce finished products (e.g., semiconductors) and/or may diminish the quality of the finished products.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In various embodiments, a reactor system is provided. The reactor system disclosed herein may comprise a plurality of reaction chambers; a plurality of transfer chambers; and/or at least two gate valves coupled to each reaction chamber of the plurality of reaction chambers. A first gate valve of the at least two gate valves may fluidly couple a first respective reaction chamber of the plurality of reaction chambers to a first transfer chamber of the plurality of transfer chambers, and a second gate valve of the at least two gate valves may fluidly couple the first respective reaction chamber to a second transfer chamber of the plurality of transfer chambers. In various embodiments, each of the plurality of transfer chambers may comprise a transfer tool, wherein each transfer tool may be configured to transfer a substrate into and/or out of multiple (e.g., at least two, or a maximum of two) of the plurality of reaction chambers.

In various embodiments, a reactor system may comprise a first reaction chamber; a first reaction chamber first gate valve coupled to the first reaction chamber and configured to allow transferring a substrate into and/or out of the first reaction chamber; a first transfer chamber, wherein the first transfer chamber may be in fluid communication with the first reaction chamber via the first reaction chamber first gate valve in response to the first reaction chamber first gate valve being open, wherein the reactor system may be configured to allow transfer of the substrate between the first reaction chamber and the first transfer chamber through the first reaction chamber first gate valve; a first reaction chamber second gate valve coupled to the first reaction chamber and configured to allow transferring a substrate into and/or out of the first reaction chamber; and/or a second transfer chamber in fluid communication with the first reaction chamber via of the first reaction chamber second gate valve in response to the first reaction chamber second gate valve being open, wherein the reactor system may be configured to allow transfer of the substrate between the first reaction chamber and the second transfer chamber through the first reaction chamber second gate valve.

In various embodiments, the first transfer chamber and the second transfer chamber may be on opposite sides of the first reaction chamber from one another. In various embodiments, the first transfer chamber and the second transfer chamber may be disposed less than 180 degrees about the first reaction chamber from one another.

In various embodiments, a reactor system may further comprise a second reaction chamber; and a second reaction chamber first gate valve coupled to the second reaction chamber and configured to allow transferring the substrate into and/or out of the second reaction chamber. The second reaction chamber may be in fluid communication with the second transfer chamber via the second reaction chamber first gate valve in response to the second reaction chamber first gate valve being open. In various embodiments, a reactor system may further comprise a second reaction chamber second gate valve coupled to the second reaction chamber. The second reaction chamber may be in fluid communication with the first transfer chamber via the second reaction chamber second gate valve in response to the second reaction chamber second gate valve being open.

In various embodiments, a reactor system may further comprise a third transfer chamber; and/or a second reaction chamber second gate valve coupled to the second reaction chamber. The second reaction chamber may be in fluid communication with the third transfer chamber via the second reaction chamber second gate valve in response to the second reaction chamber second gate valve being open.

In various embodiments, a reactor system may further comprise a third reaction chamber; and/or a third reaction chamber first gate valve coupled to the third reaction chamber and configured to allow transferring the substrate into and/or out of the third reaction chamber. The third reaction chamber may be in fluid communication with the third transfer chamber via the third reaction chamber first gate valve in response to the third reaction chamber first gate valve being open.

In various embodiments, a reactor system may further comprise a third reaction chamber second gate valve coupled to the third reaction chamber. The third reaction chamber may be in fluid communication with at least one of the first transfer chamber or the second transfer chamber via the third reaction chamber second gate valve in response to the third reaction chamber second gate valve being open. In various embodiments, a reactor system may further comprise a fourth transfer chamber; and/or a third reaction chamber third gate valve coupled to the third reaction chamber. The third reaction chamber may be in fluid communication with the fourth transfer chamber via the third reaction chamber third gate valve in response to the third reaction chamber third gate valve being open.

In various embodiments, a reactor system may further comprise a fourth transfer chamber; and/or a third reaction chamber second gate valve coupled to the third reaction chamber. The third reaction chamber may be in fluid communication with the fourth transfer chamber via the third reaction chamber second gate valve in response to the third reaction chamber second gate valve being open. In various embodiments, a reactor system may further comprise a first reaction chamber third gate valve coupled to the first reaction chamber. The fourth transfer chamber may be in fluid communication with the first reaction chamber via the first reaction chamber third gate valve in response to the first reaction chamber third gate valve being open.

In various embodiments, a reactor system may further comprise a fourth reaction chamber; and/or a fourth reaction chamber first gate valve coupled to the fourth reaction chamber and configured to allow transferring the substrate into and/or out of the fourth reaction chamber. The fourth reaction chamber may be in fluid communication with the fourth transfer chamber via the fourth reaction chamber first gate valve in response to the fourth reaction chamber first gate valve being open. In various embodiments, a reactor system may further comprise a fourth reaction chamber second gate valve coupled to the fourth reaction chamber. The fourth reaction chamber may be in fluid communication with the first transfer chamber via the fourth reaction chamber second gate valve in response to the fourth reaction chamber second gate valve being open.

In various embodiments, a method may comprise transferring a first substrate to a first reaction chamber through a first reaction chamber first gate valve coupled to the first reaction chamber, via a first transfer tool comprised in a first transfer chamber, wherein the first reaction chamber and the first transfer chamber may be in fluid communication in response to the first reaction chamber first gate valve being opened; transferring the first substrate from the first reaction chamber through a first reaction chamber second gate valve coupled to the first reaction chamber, via a second transfer tool comprised in a second transfer chamber, wherein the second transfer chamber may be in fluid communication with the first reaction chamber in response to the first reaction chamber second gate valve being opened; transferring, via the second transfer tool, the substrate to a second reaction chamber through a second reaction chamber first gate valve coupled to the second reaction chamber, wherein the second reaction chamber may be in fluid communication with the second transfer chamber in response to the second reaction chamber first gate valve being opened; and/or transferring the substrate from the second reaction chamber. In various embodiments, the transferring the substrate from the second reaction chamber may be completed via the first transfer tool through a second reaction chamber second gate valve coupled to the second reaction chamber, wherein the second reaction chamber and the first transfer chamber may be in fluid communication in response to the second reaction chamber second gate valve being opened.

In various embodiments, the method may further comprise applying a first material to the substrate in the first reaction chamber for a first duration before the transferring the substrate from the first reaction chamber; and/or applying a second material to the substrate in the second reaction chamber for a second duration before the transferring the substrate from the second reaction chamber. The first duration and the second duration may be the same.

In various embodiments, transferring the substrate from the second reaction chamber may be completed via a third transfer tool comprised in a third transfer chamber and through a second reaction chamber second gate valve coupled to the second reaction chamber, wherein the second reaction chamber and the third transfer chamber may be in fluid communication in response to the second reaction chamber second gate valve being opened. In various embodiments, the method may further comprise applying a first material to the substrate in the first reaction chamber for a first duration before the transferring the substrate from the first reaction chamber; applying a second material to the substrate in the second reaction chamber for a second duration before the transferring the substrate from the second reaction chamber; transferring, via the third transfer tool, the substrate to a third reaction chamber through a third reaction chamber first gate valve coupled to the third reaction chamber, wherein the third reaction chamber is in fluid communication with the third transfer chamber in response to the third reaction chamber first gate valve being opened; and/or applying a third material to the substrate in the third reaction chamber for a third duration. In various embodiments, the second material and the third material may be the same, and the first duration, the second duration, and the third duration may be the same.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWINGS

The subject matter of the present disclosure is particularly pointed out and distinctly claimed in the concluding portion of the specification. A more complete understanding of the present disclosure, however, may best be obtained by referring to the detailed description and claims when considered in connection with the drawing figures, wherein like numerals denote like elements.

FIG. 1 illustrates a schematic diagram of a reactor system, in accordance with various embodiments.

FIG. 2 illustrates a schematic diagram of a reactor system.

FIG. 3 illustrates another schematic diagram of a reactor system.

FIGS. 4A-C illustrate schematic diagrams of reactor systems comprising multi-directional reaction chambers, in accordance with various embodiments.

FIGS. 5A and 5B illustrate schematic diagrams of other reactor systems comprising multi-directional reaction chambers, in accordance with various embodiments.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “substrate” may refer to any underlying material or materials that may be used, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. During each cycle the precursor may be chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. This reactant may be capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

As used herein, the term “contaminant” may refer to any unwanted material disposed within the reaction chamber that may affect the purity of a substrate or layer disposed in the reaction chamber, or any unwanted material in any component of a reactor system. The term “contaminant” may refer to, but is not limited to, unwanted deposits, metal and non-metal particles, impurities, and waste products, disposed within the reaction chamber or other components of the reactor system.

As used herein, the term “gas” may include vaporized solid and/or liquid and may be constituted by a single gas or a mixture of gases.

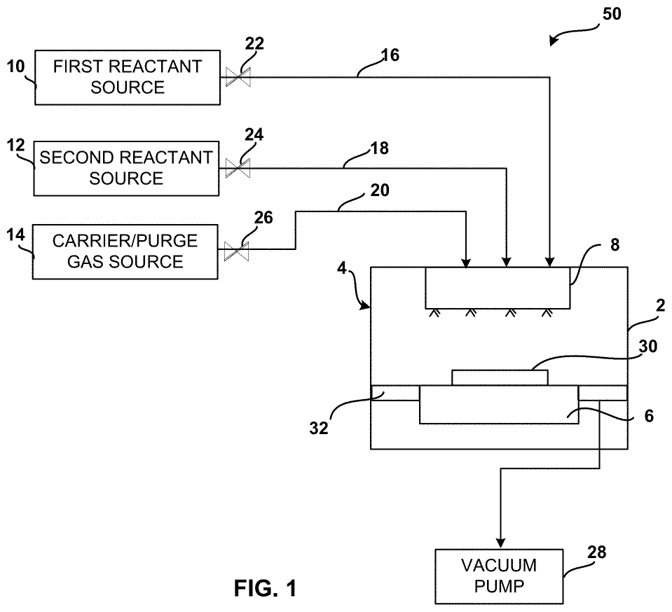

Reactor systems used for ALD, CVD, and/or the like, may be used for a variety of applications, including depositing and etching materials on a substrate surface. In various embodiments, with reference to FIG. 1, a reactor system 50 may comprise a reaction chamber 4, a susceptor 6 to hold a substrate 30 during processing, a gas distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16-20, and valves or controllers 22-26. Reactant gases or other materials from reactant sources 10, 12 may be applied to substrate 30 in reaction chamber 4. A purge gas from purge gas source 14 may be flowed to and through reaction chamber 4 to remove any excess reactant or other undesired materials from reaction chamber 4. System 50 may also comprise a vacuum source 28 fluidly coupled to the reaction chamber 4, which may be configured to suck reactants, a purge gas, and/or other materials out of reaction chamber 4.

In various embodiments, a substrate processing method may comprise multiple steps, which may be performed in multiple reaction chambers. For example, a first precursor may be applied to a substrate in one reaction chamber for a determined duration, the substrate may be transferred to another reaction chamber, and then a second precursor may be applied to the substrate. Additionally or alternatively, a first layer can be deposited in a first reaction chamber and additional reaction chamber(s) can be used for etching, cleaning, and/or for additional deposition processes. Timely transfer of a substrate between reaction chambers may facilitate more efficient substrate processing in a reactor system and/or better resulting final products (e.g., especially for final products made by processing methods having time-sensitive steps and/or involving unstable compounds that may degrade or otherwise react if processing does not continue within a desired timeframe and/or without exposure to an ambient environment).

In various embodiments, a reactor system may comprise a plurality of reaction chambers (e.g., each within a respective reactor). Each reactor and/or reaction chamber may have a surrounding wall. The surrounding wall may enclose a reaction chamber space of the reaction chamber in which a substrate may be disposed for processing. In various embodiments, a reactor system may comprise at least two gate valves coupled to each reaction chamber (e.g., coupled to the surrounding wall of each reaction chamber), wherein each gate valve may be configured to selectively allow access to the respective reaction chamber. That is, each gate valve may open to allow transfer of a substrate in and out of the respective reaction chamber (fluidly coupling the respective reaction chamber with another chamber of the reactor system, such as a transfer chamber), and close to at least partially seal the reaction chamber from the surrounding environment. For example, the gate valves for gaining access to a respective reaction chamber may be closed during substrate processing in the respective reaction chamber. Because there may be at least two gate valves coupled to each reaction chamber, and each gate valve may allow transfer of a substrate in or out of each reaction chamber to different destinations within the reactor system (e.g., other chambers), such reaction chambers may be multi-directional reaction chambers.

A reactor system may further comprise a plurality of transfer chambers. Each transfer chamber may comprise a transfer chamber surrounding wall and a transfer tool (e.g., a transfer arm) disposed therein. The transfer tool may be configured to transfer a substrate(s) in and out of one or more reaction chambers, and/or in or out of the respective transfer chamber. In various embodiments, a transfer chamber may be coupled to at least two gate valves, which allow fluid communication between other chambers in the reactor system (e.g., allowing substrate transfer therebetween). In various embodiments, each reaction chamber in the reactor system may be coupled and/or adjacent to at least two transfer chambers. Similarly, each transfer chamber may be coupled and/or adjacent to at least two reaction chambers. For example, a first of the at least two gate valves coupled to a reaction chamber may fluidly couple the reaction chamber to a first transfer chamber of the plurality of transfer chambers, such that a substrate may be transferred between the first transfer chamber and the reaction chamber in response to the respective gate valve being open. A second of the at least two gate valves coupled to the reaction chamber may fluidly couple the reaction chamber to a second transfer chamber of the plurality of transfer chambers, such that a substrate may be transferred between the second transfer chamber and the reaction chamber in response to the respective gate valve being open.

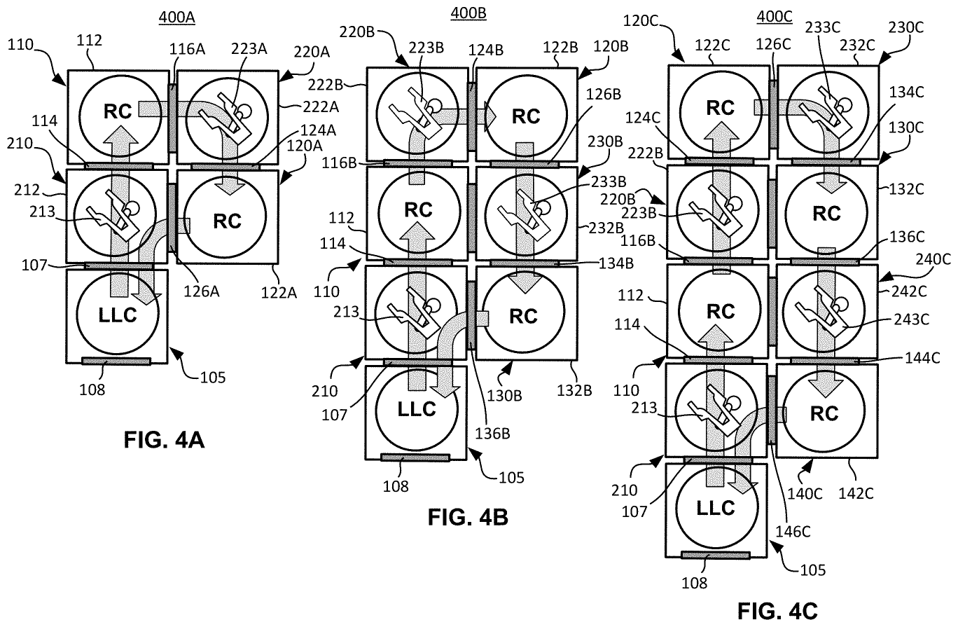

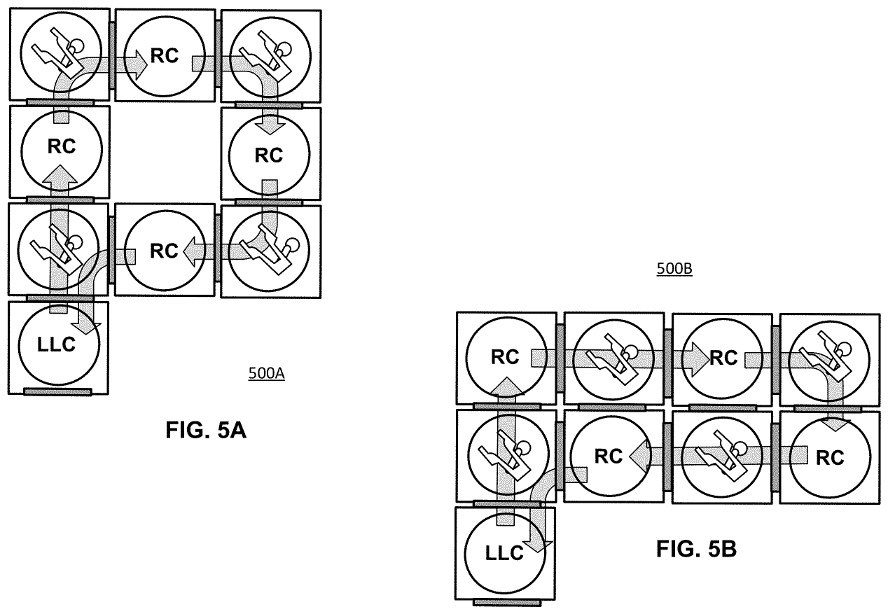

In various embodiments, a reaction chamber may be coupled to any suitable number of gate valves, each of which may couple the reaction chamber to a transfer chamber. The arrangement of the reaction chambers and transfer chambers in a reactor system may be in any suitable configuration such that each reaction chamber may be coupled to at least two gate valves, each of which fluidly couples the reaction chamber with a transfer chamber (so the reaction chamber is fluidly coupled to at least two transfer chambers, one for each gate valve), and such that each transfer chamber is coupled and/or adjacent to two or more chambers (e.g., two or three chambers, which can comprise a reaction chamber, a load lock chamber, a buffer chamber, and/or any other space from or into which a substrate may be transferred by a transfer tool in a transfer chamber). Examples of such reactor system configurations of reaction chambers and transfer chambers are illustrated in FIGS. 4A-4C, 5A and 5B, discussed further herein.

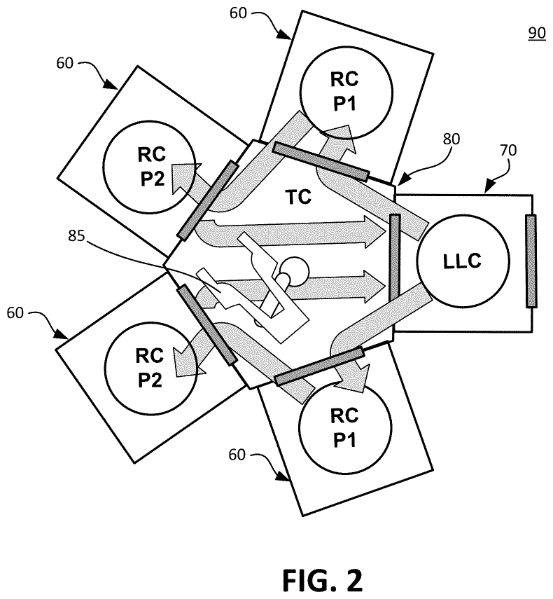

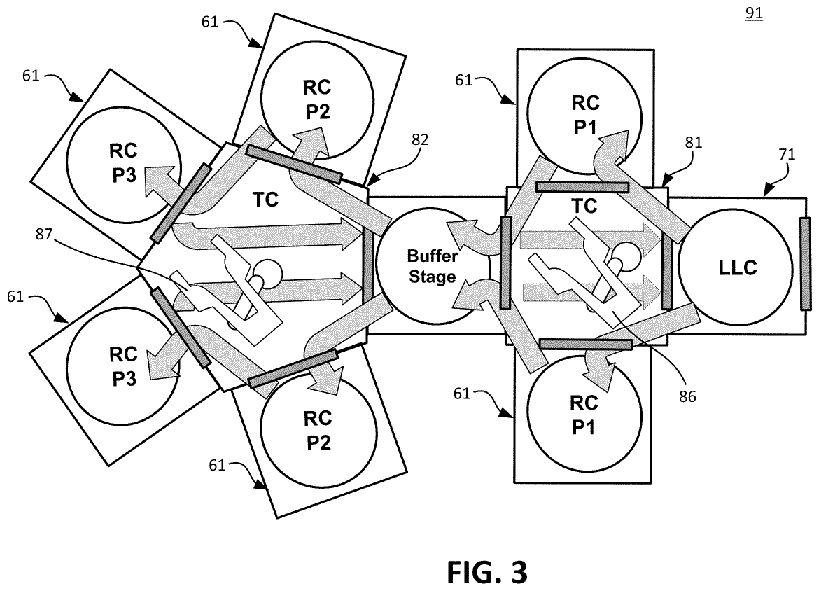

Such reactor system configurations of reaction chambers and transfer chambers may cause the number of substrate transfers for each transfer chamber to be reduced, such that any substrate transfer delays between reaction chambers are reduced or minimized. In other words, each transfer chamber may have a reduced number of possible substrate transfers (e.g., two or three), such that substrate “traffic jams” will be minimized or prevented (rather than transfer chambers having six or more possible substrate transfers, such as the in the reactor systems depicted in FIGS. 2 and 3). In various embodiments, to achieve such benefits, each transfer chamber in the reactor system may be adjacent and/or coupled to a maximum of two or three chambers (e.g., reaction chambers, load lock chambers, buffer chambers, and/or the like). Accordingly, in such embodiments, each transfer chamber and/or the transfer tool(s) comprised therein may have a maximum of two or three possible substrate transfers to perform between chambers.

With reference to FIG. 4A, a reactor system (e.g., reactor system 400A) may comprise a first reaction chamber (e.g., first reaction chamber 110). First reaction chamber 110 may comprise a first surrounding wall 112. The surrounding wall of a reaction chamber may comprise any suitable design or shape. For example, a surrounding wall of a reaction chamber may comprise a number of surrounding wall sides (e.g., three, four, six, or eight sides), wherein one or more of the surrounding wall sides is coupled to a gate valve. A gate valve may be configured to open and close, exposing or at least partially sealing, respectively, the reaction chamber space of first reaction chamber 110. In response to a gate valve being open, the reaction chamber coupled to the gate valve may be in fluid communication with another chamber in the reactor system. In response to the gate valve being closed, the reaction chamber coupled to the gate valve may be at least partially sealed from another chamber in the reactor system (e.g., an adjacent chamber). As depicted in FIG. 4A, first reaction chamber 110 may be coupled to a first reaction chamber first gate valve 114. First reaction chamber first gate valve 114 may allow the transfer of a substrate in and out of first reaction chamber 110.

In various embodiments, reactor system 400A may comprise a first transfer chamber 210 having a first transfer chamber surrounding wall 212. First transfer chamber 210 may be disposed adjacent to, and/or coupled to, first reaction chamber 110 and/or first reaction chamber first gate valve 114. First reaction chamber first gate valve 114 may cause first reaction chamber 110 and first transfer chamber 210 to be in fluid communication (e.g., in response to first reaction chamber first gate valve 114 being open). Thus, a first transfer tool 213 comprised in first transfer chamber 210 may be able to transfer one or more substrates in and out of first reaction chamber 110 through first reaction chamber first gate valve 114.

Another chamber of the reactor system (e.g., reactor system 400A) may be adjacent and/or coupled to first transfer chamber 210, from which first transfer tool 213 may receive substrates to be transferred to first reaction chamber 110 and/or to which first transfer tool 213 may transfer substrates from first reaction chamber 110 and/or another chamber in reactor system 400A. In various embodiments, a load lock chamber (LLC) 105 may be coupled and/or adjacent to first transfer chamber 210. LLC 105 may be configured to hold substrates awaiting processing and/or substrates which have been processed. Therefore, first transfer chamber 210 may transfer substrates awaiting processing from LLC 105 to first reaction chamber 110 and/or transfer finished products (e.g., processed substrates) from a final reaction chamber used in the process to LLC 105. The final reaction chamber in a reactor system may be the last reaction chamber used in a process, or the reaction chamber from which substrates may be loaded into an LLC by a transfer chamber after processing. The first transfer chamber in a reactor system, in the embodiments disclosed herein, may be the transfer chamber configured to retrieve and/or deliver substrates to and from the LLC. The first transfer chamber and the LLC may be coupled to an LLC gate valve (e.g., LLC gate valve 107), through which a substrate(s) may be transferred between the first transfer chamber and the LLC.

In various embodiments, reactor system 400A may comprise a second transfer chamber 220A having a second transfer chamber surrounding wall 222A. Second transfer chamber 220A may be coupled and/or adjacent to first reaction chamber 110. Reactor system 400A may further comprise a first reaction chamber second gate valve 116A coupled to first reaction chamber 110 and/or second transfer chamber 220A. Second transfer chamber 220A may be coupled and/or disposed adjacent to first reaction chamber 110 and/or first reaction chamber second gate valve 116A. First reaction chamber second gate valve 116A may cause first reaction chamber 110 and second transfer chamber 220A to be in fluid communication (e.g., in response to first reaction chamber second gate valve 116A being open). Thus, a second transfer tool 223A comprised in second transfer chamber 220A may be able to transfer one or more substrates in and out of first reaction chamber 110 through first reaction chamber second gate valve 116A.

First transfer chamber 210 and second transfer chamber 220A may be coupled to first reaction chamber 110 in any suitable configuration relative to one another. In various embodiments, first transfer chamber 210 and second transfer chamber 220A may be disposed on opposite sides of first reaction chamber 110 from one another. In various embodiments, first transfer chamber 210 and second transfer chamber 220A may be disposed 180 degrees from one another with first reaction chamber 110 therebetween. In various embodiments, first transfer chamber 210 and second transfer chamber 220A may be disposed less than 180 degrees from one another (e.g., about 90 degrees, about 120 degrees, or about 60 degrees from one another). In this context, “about” means plus or minus 20 or 30 degrees. As depicted in reactor system 400A, first transfer chamber 210 and second transfer chamber 220A may be disposed 90 degrees from one another.

In various embodiments, a reactor system (e.g., reactor system 400A) may comprise a second reaction chamber (e.g., second reaction chamber 120A). Second reaction chamber 120A may comprise a second surrounding wall 122A. Second reaction chamber 120A may be adjacent and/or coupled to second transfer chamber 220A.

Reactor system 400A may comprise a second reaction chamber first gate valve 124A coupled to second reaction chamber 120A and/or second transfer chamber 220A. Second reaction chamber first gate valve 124A, in response to being open, may fluidly couple second transfer chamber 220A and second reaction chamber 120A, such that transfer of a substrate in and out of second reaction chamber 120A may occur through second reaction chamber first gate valve 124A. Such substrate transfer may be accomplished by second transfer tool 223A.

In various embodiments, reactor system 400A may further comprise a second reaction chamber second gate valve 126A. Second reaction chamber second gate valve 126A may be coupled to second reaction chamber 120A and/or first transfer chamber 210. Second reaction chamber second gate valve 126A, in response to being open, may fluidly couple second reaction chamber 120A and first transfer chamber 210, such that transfer of a substrate in and out of second reaction chamber 120A may occur through second reaction chamber second gate valve 126A. Such substrate transfer may be accomplished by first transfer tool 213. Second reaction chamber 120A and first transfer chamber 210 may be adjacent and/or coupled.

In the configuration of chambers shown in reactor system 400A, second reaction chamber 120A may be the final reaction chamber, from which substrates are transferred to LLC 105 after processing. Thus, in various embodiments, a reactor system (e.g., reactor system 400A) may comprise two reaction chambers and two transfer chambers arranged in two columns of two chambers each (i.e., a two-by-two arrangement), with an LLC coupled to one at least one of the transfer chambers (e.g., the first transfer chamber). The LLC may be coupled to a transfer chamber in any suitable position. For example, the LLC may be positioned closer to one reaction chamber in the reactor system than another reaction chamber. Referring to reactor system 400A, LLC 105 is positioned on an opposite side of first transfer chamber 210 than first reaction chamber 110 (and thus, closer to second reaction chamber 120A), but in various embodiments, for example, LLC 105 may be positioned on an opposite side of first transfer chamber 210 than second reaction chamber 120A (and thus, closer to first reaction chamber 110).

The reaction chambers in reactor system 400A each have at least two gate valves coupled thereto, and therefore, are multi-directional reaction chambers because there are more than one entrance/exit for a substrate to be transferred in and out of each reaction chamber.

To process a substrate in reactor system 400A, a substrate may be transferred from LLC 105 to first reaction chamber 110 through first transfer chamber 210 via first transfer tool 213. First transfer tool 213 may obtain the substrate from LLC 105 through LLC gate valve 107 (in response to LLC gate valve 107 being open), and transfer the substrate to first transfer chamber 210. After the substrate enters and/or is disposed in first transfer chamber 210 from LLC 105, LLC gate valve 107 may close and/or first reaction chamber first gate valve 114 may open. First transfer tool 213 may deliver the substrate to first reaction chamber 110 through first reaction chamber first gate valve 114 (in response to first reaction chamber first gate valve 114 being open). After the substrate enters and/or is disposed in first reaction chamber 110, first reaction chamber first gate valve 114 may close to at least partially seal first reaction chamber 110 so one or more processing steps may occur (e.g., application of one or more gases (such as reactant gases and/or purge gases) to the substrate in first reaction chamber 110). During processing of the substrate in first reaction chamber 110, first reaction chamber second gate valve 116A may also be closed to at least partially seal first reaction chamber 110.

After completion of the processing of the substrate in first reaction chamber 110, first reaction chamber second gate valve 116A may open and second transfer tool 223A may obtain the substrate from first reaction chamber 110 and transfer the substrate to second transfer chamber 220A. After the substrate enters and/or is disposed in second transfer chamber 220A from first reaction chamber 110, first reaction chamber second gate valve 116A may close and/or second reaction chamber first gate valve 124A may open. Second transfer tool 223A may deliver the substrate to second reaction chamber 120A through second reaction chamber first gate valve 124A (in response to second reaction chamber first gate valve 124A being open). After the substrate enters and/or is disposed in second reaction chamber 120A, second reaction chamber first gate valve 124A may close to at least partially seal second reaction chamber 120A so one or more processing steps may occur to the substrate in second reaction chamber 120A. During processing of the substrate in second reaction chamber 120A, second reaction chamber second gate valve 126A may also be closed to at least partially seal second reaction chamber 120A.

After completion of the processing of the substrate in second reaction chamber 120A, second reaction chamber second gate valve 126A may open and first transfer tool 213 may obtain the substrate from second reaction chamber 120A and transfer the substrate to first transfer chamber 210 (or to first reaction chamber 110 again for further processing). An LLC may be coupled to another gate valve (e.g., gate valve 108), which may be configured to allow loading of substrates for processing into the LLC (e.g., by an operator of the reactor system) or unloaded processed substrates from the LLC.

The processing occurring in first reaction chamber 110 and/or second reaction chamber 120A may comprise the same or different processing of the substrate. That is, a first process may occur in first reaction chamber 110 and a second process may occur in second reaction chamber 120A, for any suitable duration, with any suitable number of steps. For example, a process may comprise two steps (e.g., applying a first material to the substrate and then applying a second material to the substrate), wherein one step is performed in first reaction chamber 110 and the other is performed in second reaction chamber 120A. As another example, a process may comprise one step, which may comprise a processing duration. The entire processing duration may be performed in either first reaction chamber 110 or second reaction chamber 120A, or processing for one-half of the duration may occur in first reaction chamber 110 and processing for the other half of the duration may occur in second reaction chamber 120A. It should be noted that the substrate may travel between the chambers in a reactor system in any suitable order (e.g., an order that is the reverse of that described herein).

With reference to FIG. 4B, a reactor system 400B may comprise LLC 105, LLC gate valve 107, first transfer chamber 210, first reaction chamber 110, and first reaction chamber first gate valve 114, and any components therein, similar to reactor system 400A of FIG. 4A, discussed herein. In various embodiments, reactor system 400B may comprise a second transfer chamber 220B coupled and/or adjacent to first reaction chamber 110. Unlike second transfer chamber 220A in reactor system 400A, second transfer chamber 220B may be on an opposite side of first reaction chamber 110 than first transfer chamber 210. Reactor system 400B may comprise a first reaction chamber second gate valve 116B coupled to first reaction chamber 110 and/or second transfer chamber 220B. First reaction chamber second gate valve 116B may cause first reaction chamber 110 and second transfer chamber 220B to be in fluid communication (e.g., in response to first reaction chamber second gate valve 116B being open). Thus, a second transfer tool 223B comprised in second transfer chamber 220B may be able to transfer one or more substrates in and out of first reaction chamber 110 through first reaction chamber second gate valve 116B.

In various embodiments, a reactor system (e.g., reactor system 400B) may comprise a second reaction chamber (e.g., second reaction chamber 120B). Second reaction chamber 120B may comprise a second surrounding wall 122B. Second reaction chamber 120B may be adjacent and/or coupled to second transfer chamber 220A.

Reactor system 400B may comprise a second reaction chamber first gate valve 124B coupled to second reaction chamber 120B and/or to second transfer chamber 220B. Second reaction chamber first gate valve 124B, in response to being open, may fluidly couple second transfer chamber 220B and second reaction chamber 120B, such that transfer of a substrate in and out of second reaction chamber 120B may occur through second reaction chamber first gate valve 124B. Such substrate transfer may be accomplished by second transfer tool 223B.

In various embodiments, reactor system 400B may comprise a third transfer chamber (e.g., third transfer chamber 230B). Third transfer chamber 230B may comprise a third surrounding wall 232B. Third transfer chamber 230B may be adjacent and/or coupled to second reaction chamber 120B. Third transfer chamber 230B may comprise a third transfer tool 233B configured to transfer substrates in and out of third transfer chamber 230B.

In various embodiments, reactor system 400B may further comprise a second reaction chamber second gate valve 126B. Second reaction chamber second gate valve 126B may be coupled to second reaction chamber 120B and/or third transfer chamber 230B. Second reaction chamber second gate valve 126B, in response to being open, may fluidly couple second reaction chamber 120B and third transfer chamber 230B, such that transfer of a substrate in and out of second reaction chamber 120B may occur through second reaction chamber second gate valve 126B. Such substrate transfer may be accomplished by third transfer tool 233B.

In various embodiments, a reactor system (e.g., reactor system 400B) may comprise a third reaction chamber (e.g., third reaction chamber 130B). Third reaction chamber 130B may comprise a third surrounding wall 132B. Third reaction chamber 130B may be adjacent and/or coupled to third transfer chamber 230B.

Reactor system 400B may comprise a third reaction chamber first gate valve 134B coupled to third reaction chamber 130B and/or third transfer chamber 230B. Third reaction chamber first gate valve 134B, in response to being open, may fluidly couple third transfer chamber 230B and third reaction chamber 130B, such that transfer of a substrate in and out of third reaction chamber 130B may occur through third reaction chamber first gate valve 134B. Such substrate transfer may be accomplished by third transfer tool 233B.

In various embodiments, reactor system 400B may further comprise a third reaction chamber second gate valve 136B. Third reaction chamber second gate valve 136B may be coupled to third reaction chamber 130B and/or first transfer chamber 210. Third reaction chamber second gate valve 136B, in response to being open, may fluidly couple third reaction chamber 130B and first transfer chamber 210, such that transfer of a substrate in and out of third reaction chamber 130B may occur through third reaction chamber second gate valve 136B. Such substrate transfer may be accomplished by first transfer tool 213. Third reaction chamber 130B and first transfer chamber 210 may be adjacent and/or coupled.

In the configuration of chambers shown in reactor system 400B, third reaction chamber 130B may be the final reaction chamber, from which substrates are transferred to LLC 105 after processing. Thus, in various embodiments, a reactor system (e.g., reactor system 400B) may comprise three reaction chambers and three transfer chambers arranged in two columns of three chambers each (i.e., a two-by-three arrangement), or arranged in two rows of three chambers each (i.e., a three-by-two arrangement), with an LLC coupled to at least one of the transfer chambers (e.g., the first transfer chamber). The LLC may be coupled to a transfer chamber in any suitable position. For example, the LLC may be positioned closer to one reaction chamber in the reactor system than another reaction chamber. Referring to reactor system 400B, LLC 105 is positioned on an opposite side of first transfer chamber 210 than first reaction chamber 110 (and thus, closer to third reaction chamber 130B), but in various embodiments, for example, LLC 105 may be positioned on an opposite side of first transfer chamber 210 than third reaction chamber 130B (and thus, closer to first reaction chamber 110).

The reaction chambers in reactor system 400B each have at least two gate valves coupled thereto, and therefore, are multi-directional reaction chambers because there are more than one entrance/exit for a substrate to be transferred in and out of each reaction chamber.

To process a substrate in reactor system 400B, a substrate may be transferred from LLC 105 to first reaction chamber 110 through first transfer chamber 210 and via first transfer tool 213. First transfer tool 213 may obtain the substrate from LLC 105 through LLC gate valve 107 (in response to LLC gate valve 107 being open), and transfer the substrate to first transfer chamber 210. After the substrate enters and/or is disposed in first transfer chamber 210 from LLC, LLC gate valve 107 may close and/or first reaction chamber first gate valve 114 may open. First transfer tool 213 may deliver the substrate to first reaction chamber 110 through first reaction chamber first gate valve 114 (in response to first reaction chamber first gate valve 114 being open). After the substrate enters and/or is disposed in first reaction chamber 110, first reaction chamber first gate valve 114 may close to at least partially seal first reaction chamber 110 so one or more processing steps may occur (e.g., application of one or more gases (such as reactant gases and/or purge gases) to the substrate in first reaction chamber 110). During processing of the substrate in first reaction chamber 110, first reaction chamber second gate valve 116B may also be closed to at least partially seal first reaction chamber 110.

After completion of the processing of the substrate in first reaction chamber 110, first reaction chamber second gate valve 116B may open and second transfer tool 223B may obtain the substrate from first reaction chamber 110 and transfer the substrate to second transfer chamber 220B. After the substrate enters and/or is disposed in second transfer chamber 220B from first reaction chamber 110, first reaction chamber second gate valve 116B may close and/or second reaction chamber first gate valve 124B may open. Second transfer tool 223B may deliver the substrate to second reaction chamber 120B through second reaction chamber first gate valve 124B (in response to second reaction chamber first gate valve 124B being open). After the substrate enters and/or is disposed in second reaction chamber 120B, second reaction chamber first gate valve 124B may close to at least partially seal second reaction chamber 120B so one or more processing steps may occur to the substrate in second reaction chamber 120B. During processing of the substrate in second reaction chamber 120B, second reaction chamber second gate valve 126B may also be closed to at least partially seal second reaction chamber 120B.

After completion of the processing of the substrate in second reaction chamber 120B, second reaction chamber second gate valve 126B may open and third transfer tool 233B may obtain the substrate from second reaction chamber 120B and transfer the substrate to third transfer chamber 230B. After the substrate enters and/or is disposed in third transfer chamber 230B from second reaction chamber 120B, second reaction chamber second gate valve 126B may close and/or third reaction chamber first gate valve 134B may open. Third transfer tool 233B may deliver the substrate to third reaction chamber 130B through third reaction chamber first gate valve 134B (in response to third reaction chamber first gate valve 134B being open). After the substrate enters and/or is disposed in third reaction chamber 130B, third reaction chamber first gate valve 134B may close to at least partially seal third reaction chamber 130B so one or more processing steps may occur to the substrate in third reaction chamber 130B. During processing of the substrate in third reaction chamber 130B, third reaction chamber second gate valve 136B may also be closed to at least partially seal third reaction chamber 130B.

After completion of the processing of the substrate in third reaction chamber 130B, third reaction chamber second gate valve 136B may open and first transfer tool 213 may obtain the substrate from third reaction chamber 130B and transfer the substrate to first transfer chamber 210 (or to first reaction chamber 110 again for further processing).

The processing occurring in first reaction chamber 110, second reaction chamber 120B, and/or third reaction chamber 130B may comprise the same or different processing of the substrate. That is, a first process may occur in first reaction chamber 110, a second process may occur in second reaction chamber 120B, and/or a third process may occur in third reaction chamber 130B, for any suitable duration, with any suitable number of steps. For example, a process may comprise three steps, wherein one step is performed in first reaction chamber 110, one step is performed in second reaction chamber 120B, and the final step is performed in third reaction chamber 130B (e.g., with each step having equal or different durations). As another example, processing a substrate may comprise one step (e.g., applying a first material to the substrate for a first duration) and a second step (e.g., applying a second material to the substrate for a second duration). However, the second duration may be longer (e.g., twice as long) as the first duration. Therefore, the first step may be performed in first reaction chamber 110, and the second step may be split between second reaction chamber 120B and third reaction chamber 130B (e.g., a second material being applied to the substrate in second reaction chamber 120B for half of the second duration (which may be equal to the first duration), and a third material being applied to the substrate in third reaction chamber 130B for the other half of the second duration (which may be the same as the second material to complete the second step of the process). In this example, the process steps may be spread out between the reaction chambers such that the substrates continually advance through the chambers of the reactor system such that substrate transfer delays between chambers (i.e., a substrate that has finished a process step in a reaction chamber waiting in the reaction chamber or the next transfer chamber to enter the subsequent reaction chamber) are minimized or prevented. As yet another example, a process may comprise one step, which may comprise a processing duration. The entire processing duration may be performed in either first reaction chamber 110, second reaction chamber 120B, and/or third reaction chamber 130B, or processing for one-third of the duration may occur in first reaction chamber 110, processing for a second one-third of the duration may occur in second reaction chamber 120B, and processing for the final one-third of the duration may occur in third reaction chamber 130B (or any other division of processing and/or processing duration between at least some of the reaction chambers). It should be noted that the substrate may travel between the chambers in a reactor system in any suitable order (e.g., an order that is the reverse of that described herein).

With reference to FIG. 4C, a reactor system 400C may comprise LLC 105, LLC gate valve 107, first transfer chamber 210, first reaction chamber 110, and first reaction chamber first gate valve 114, and any components therein, similar to reactor systems 400A and 400B, discussed herein. Additionally, reactor system 400C may comprise first reaction chamber second gate valve 116B and second transfer chamber 220B, and any components therein, similar to reactor system 400B. In various embodiments, reactor system 400C may comprise a second transfer chamber 220B coupled and/or adjacent to first reaction chamber 110. Reactor system 400C may comprise a first reaction chamber second gate valve 116B coupled to first reaction chamber 110 and/or second transfer chamber 220B. First reaction chamber second gate valve 116B may cause first reaction chamber 110 and second transfer chamber 220B to be in fluid communication (e.g., in response to first reaction chamber second gate valve 116B being open). Thus, a second transfer tool 223B comprised in second transfer chamber 220B may be able to transfer one or more substrates in and out of first reaction chamber 110 through first reaction chamber second gate valve 116B.

In various embodiments, a reactor system (e.g., reactor system 400C) may comprise a second reaction chamber (e.g., second reaction chamber 120C). Second reaction chamber 120C may comprise a second surrounding wall 122C. Second reaction chamber 120C may be coupled to second transfer chamber 220B. Second reaction chamber 120C may be positioned opposite from 110, with second transfer chamber 220B therebetween between. As discussed herein, the chambers may be positioned in any suitable arrangement, so second reaction chamber 120C may be positioned relative first reaction chamber 110 with second transfer chamber 220B therebetween in any suitable manner.

Reactor system 400C may comprise a second reaction chamber first gate valve 124C coupled to second reaction chamber 120C and/or second transfer chamber 220B. Second reaction chamber first gate valve 124C, in response to being open, may fluidly couple second transfer chamber 220B and second reaction chamber 120C, such that transfer of a substrate in and out of second reaction chamber 120C may occur through second reaction chamber first gate valve 124C. Such substrate transfer may be accomplished by second transfer tool 223B.

In various embodiments, reactor system 400C may comprise a third transfer chamber (e.g., third transfer chamber 230C). Third transfer chamber 230C may comprise a third surrounding wall 232C. Third transfer chamber 230C may be adjacent and/or coupled to second reaction chamber 120C. Third transfer chamber 230C may comprise a third transfer tool 233C configured to transfer substrates in and out of second reaction chamber 120C.

In various embodiments, 400C may further comprise a second reaction chamber second gate valve 126C. Second reaction chamber second gate valve 126C may be coupled to second reaction chamber 120C and/or third transfer chamber 230C. Second reaction chamber second gate valve 126C, in response to being open, may fluidly couple second reaction chamber 120C and third transfer chamber 230C, such that transfer of a substrate in and out of second reaction chamber 120C may occur through second reaction chamber second gate valve 126C. Such substrate transfer may be accomplished by third transfer tool 233C.

In various embodiments, a reactor system (e.g., reactor system 400C) may comprise a third reaction chamber (e.g., third reaction chamber 130C). Third reaction chamber 130C may comprise a third surrounding wall 132C. Third reaction chamber 130C may be adjacent and/or coupled to third transfer chamber 230C. In various embodiments, third reaction chamber 130C may be adjacent and/or coupled to second transfer chamber 230B.

Reactor system 400BC may comprise a third reaction chamber first gate valve 134C, which may be coupled to third reaction chamber 130C and/or third transfer chamber 230C. Third reaction chamber first gate valve 134C, in response to being open, may fluidly couple third transfer chamber 230C and third reaction chamber 130C, such that transfer of a substrate in and out of third reaction chamber 130C may occur through third reaction chamber first gate valve 134C. Such substrate transfer may be accomplished by third transfer tool 233C.

In various embodiments, reactor system 400C may comprise a fourth transfer chamber (e.g., fourth transfer chamber 240C). Fourth transfer chamber 240C may comprise a fourth surrounding wall 242C. Fourth transfer chamber 240C may be adjacent and/or coupled to third reaction chamber 130C. In various embodiments, fourth transfer chamber 240C may be adjacent and/or coupled to first reaction chamber 110. Fourth transfer chamber 240C may comprise a fourth transfer tool 243C configured to transfer substrates in and out of third reaction chamber 130C.

In various embodiments, 400C may further comprise a third reaction chamber second gate valve 136C. Third reaction chamber second gate valve 136C may be coupled to third reaction chamber 130C and/or fourth transfer chamber 240C. Third reaction chamber second gate valve 136C, in response to being open, may fluidly couple third reaction chamber 130C and fourth transfer chamber 240C, such that transfer of a substrate in and out of third reaction chamber 130C may occur through third reaction chamber second gate valve 136C. Such substrate transfer may be accomplished by fourth transfer tool 243C.

In various embodiments, a reactor system (e.g., reactor system 400C) may comprise a fourth reaction chamber (e.g., fourth reaction chamber 140C). Fourth reaction chamber 140C may comprise a third surrounding wall 142C. Fourth reaction chamber 140C may be adjacent and/or coupled to fourth transfer chamber 240C. In various embodiments, fourth reaction chamber 140C may be adjacent and/or coupled to first transfer chamber 210.

In various embodiments, reactor system 400C may comprise a fourth reaction chamber first gate valve 144C, which may be coupled to fourth reaction chamber 140C and/or fourth transfer chamber 240C. Fourth reaction chamber first gate valve 144C, in response to being open, may fluidly couple fourth reaction chamber 140C and fourth transfer chamber 240C, such that transfer of a substrate in and out of fourth reaction chamber 140C may occur through fourth reaction chamber first gate valve 144C. Such substrate transfer may be accomplished by fourth transfer tool 243C.

In various embodiments, reactor system 400C may further comprise a fourth reaction chamber second gate valve 146C. Fourth reaction chamber second gate valve 146C may be coupled to fourth reaction chamber 140C and/or first transfer chamber 210. Fourth reaction chamber second gate valve 146C, in response to being open, may fluidly couple fourth reaction chamber 140C and first transfer chamber 210, such that transfer of a substrate in and out of fourth reaction chamber 140C may occur through fourth reaction chamber second gate valve 146C. Such substrate transfer may be accomplished by first transfer tool 213. Fourth reaction chamber 140C and first transfer chamber 210 may be adjacent and/or coupled.

In the configuration of chambers shown in reactor system 400C, fourth reaction chamber 140C may be the final reaction chamber, from which substrates are transferred to LLC 105 after processing. Thus, in various embodiments, a reactor system (e.g., reactor system 400C) may comprise four reaction chambers and four transfer chambers arranged in two columns of four chambers each (i.e., a two-by-four arrangement), or arranged in two rows of four chambers each (i.e., a four-by-two arrangement) with an LLC coupled to at least one of the transfer chambers (e.g., the first transfer chamber). The LLC may be coupled to a transfer chamber in any suitable position. For example, the LLC may be positioned closer to one reaction chamber in the reactor system than another reaction chamber. Referring to reactor system 400C, LLC 105 is positioned on an opposite side of first transfer chamber 210 than first reaction chamber 110 (and thus, closer to fourth reaction chamber 140C), but in various embodiments, for example, LLC 105 may be positioned on an opposite side of first transfer chamber 210 than fourth reaction chamber 140C (and thus, closer to first reaction chamber 110), similar to the chamber arrangement in reactor system 500B of FIG. 5B.

The reaction chambers in reactor system 400C each have at least two gate valves coupled thereto, and therefore, are multi-directional reaction chambers because there are more than one entrance/exit for a substrate to be transferred in and out of each reaction chamber.

To process a substrate in reactor system 400C, a substrate may be transferred from LLC 105 to first reaction chamber 110 through first transfer chamber 210 and via first transfer tool 213. First transfer tool 213 may obtain the substrate from LLC 105 through LLC gate valve 107 (in response to LLC gate valve 107 being open), and transfer the substrate to first transfer chamber 210. After the substrate enters and/or is disposed in first transfer chamber 210 from LLC 105, LLC gate valve 107 may close and/or first reaction chamber first gate valve 114 may open. First transfer tool 213 may deliver the substrate to first reaction chamber 110 through first reaction chamber first gate valve 114 (in response to first reaction chamber first gate valve 114 being open). After the substrate enters and/or is disposed in first reaction chamber 110, first reaction chamber first gate valve 114 may close to at least partially seal first reaction chamber 110 so one or more processing steps may occur (e.g., application of one or more gases (such as reactant gases and/or purge gases) to the substrate in first reaction chamber 110). During processing of the substrate in first reaction chamber 110, first reaction chamber second gate valve 116B may also be closed to at least partially seal first reaction chamber 110.

After completion of the processing of the substrate in first reaction chamber 110, first reaction chamber second gate valve 116B may open and second transfer tool 223B may obtain the substrate from first reaction chamber 110 and transfer the substrate to second transfer chamber 220B. After the substrate enters and/or is disposed in second transfer chamber 220B from first reaction chamber 110, first reaction chamber second gate valve 116B may close and/or second reaction chamber first gate valve 124C may open. Second transfer tool 223B may deliver the substrate to second reaction chamber 120C through second reaction chamber first gate valve 124C (in response to second reaction chamber first gate valve 124C being open). After the substrate enters and/or is disposed in second reaction chamber 120C, second reaction chamber first gate valve 124C may close to at least partially seal second reaction chamber 120C so one or more processing steps may occur to the substrate in second reaction chamber 120C. During processing of the substrate in second reaction chamber 120C, second reaction chamber second gate valve 126C may also be closed to at least partially seal second reaction chamber 120C.

After completion of the processing of the substrate in second reaction chamber 120C, second reaction chamber second gate valve 126C may open and third transfer tool 233C may obtain the substrate from second reaction chamber 120C and transfer the substrate to third transfer chamber 230C. After the substrate enters and/or is disposed in third transfer chamber 230C from second reaction chamber 120C, second reaction chamber second gate valve 126C may close and/or third reaction chamber first gate valve 134C may open. Third transfer tool 233C may deliver the substrate to third reaction chamber 130C through third reaction chamber first gate valve 134C (in response to third reaction chamber first gate valve 134C being open). After the substrate enters and/or is disposed in third reaction chamber 130C, third reaction chamber first gate valve 134C may close to at least partially seal third reaction chamber 130C so one or more processing steps may occur to the substrate in third reaction chamber 130C. During processing of the substrate in third reaction chamber 130C, third reaction chamber second gate valve 136C may also be closed to at least partially seal third reaction chamber 130C.

After completion of the processing of the substrate in third reaction chamber 130C, fourth transfer tool 243C may obtain the substrate from third reaction chamber 130C and transfer the substrate to fourth transfer chamber 240C. After the substrate enters and/or is disposed in fourth transfer chamber 240C from third reaction chamber 130C, third reaction chamber second gate valve 136C may close and/or fourth reaction chamber first gate valve 144C may open. Fourth transfer tool 243C may deliver the substrate to fourth reaction chamber 140C through fourth reaction chamber first gate valve 144C (in response to fourth reaction chamber first gate valve 144C being open). After the substrate enters and/or is disposed in fourth reaction chamber 140C, fourth reaction chamber first gate valve 144C may close to at least partially seal fourth reaction chamber 140C so one or more processing steps may occur to the substrate in fourth reaction chamber 140C. During processing of the substrate in fourth reaction chamber 140C, fourth reaction chamber second gate valve 146C may also be closed to at least partially seal fourth reaction chamber 140C.

After completion of the processing of the substrate in fourth reaction chamber 140C, fourth reaction chamber second gate valve 146C may open and first transfer tool 213 may obtain the substrate from fourth reaction chamber 140C and transfer the substrate to first transfer chamber 210 (or to first reaction chamber 110 again for further processing).

The processing occurring in first reaction chamber 110, second reaction chamber 120C, third reaction chamber 130C, and/or fourth reaction chamber 140C may comprise the same or different processing of the substrate. That is, a first process may occur in first reaction chamber 110, a second process may occur in second reaction chamber 120C, a third process may occur in third reaction chamber 130C, and/or a fourth process may occur in fourth reaction chamber 140C for any suitable duration, with any suitable number of steps. For example, a process may comprise four steps, wherein one step is performed in first reaction chamber 110, one step is performed in second reaction chamber 120C, another step is performed in third reaction chamber 130C, and a final step is performed in fourth reaction chamber 140C (e.g., with each step having equal or different durations). As another example, processing a substrate may comprise one step (e.g., applying a first material to the substrate for a first duration) and a second step (e.g., applying a second material to the substrate for a second duration). However, the second duration may be longer (e.g., three times as long) as the first duration. Therefore, the first step may be performed in first reaction chamber 110, and the second step may be split between second reaction chamber 120C, third reaction chamber 130C, and fourth reaction chamber 140C (e.g., a second material being applied to the substrate in second reaction chamber 120C for one-third of the second duration (one-third of the second duration may be equal to the first duration), a third material being applied to the substrate in third reaction chamber 130C for another third of the second duration, and a fourth material being applied to the substrate in fourth reaction chamber 140C for the final third of the second duration (the first, second, and third materials all may be the same material to complete the second step of the process). In this example, the process steps may be spread out between the reaction chambers such that the substrates continually advance through the chambers of the reactor system such that substrate transfer delays between chambers (i.e., a substrate that has finished a process step in a reaction chamber waiting in the reaction chamber or the next transfer chamber to enter the subsequent reaction chamber) are mitigated or prevented. As yet another example, a process may comprise one step, which may comprise a processing duration. The entire processing duration may be performed in either first reaction chamber 110, second reaction chamber 120C, third reaction chamber 130C, and/or fourth reaction chamber 140C, or processing for one-fourth of the duration may occur in each of first reaction chamber 110, second reaction chamber 120C, third reaction chamber 130C, and/or fourth reaction chamber 140C (or any other division of processing and/or processing duration between at least some of the reaction chambers). As yet another example, a process may comprise two steps: a first step having a first duration and the second step having a second duration. The first step may be performed in first reaction chamber 110 for half of the first duration and in second reaction chamber 120C for the second half of the first duration, and the second step may be performed in third reaction chamber 130C for half of the second duration and in fourth reaction chamber 140C for the second half of the second duration.

It should be noted that the arrows depicted in FIGS. 4A-4C and 5A and 5B are for illustrative purposes only, and that substrates may be transferred between chambers in a reaction chamber in any suitable manner or order. Similarly, designation of “first,” “second,” “third,” etc. of chambers, gate valves, etc. within reactor system do not necessarily indicate an order through in which a substrate may be transferred, or a chamber or gate valve order or arrangement (i.e., which chambers and/or gate valves may be proximate or adjacent to one another).

In various embodiments, a reactor system may comprise additional gate valves coupled between chambers other than those discussed in relation to reactor systems 400A, 400B, and 400C. For example, referring to reactor system 400B in FIG. 4B, there may be a gate valve coupled to first reaction chamber 110 and/or third transfer chamber 230B (which may be a first reaction chamber third gate valve), such that third transfer tool 233B may transfer a substrate in or out of first reaction chamber 110 (e.g., to bypass second reaction chamber 120B or third reaction chamber 130B). As another example, referring to reactor system 400C in FIG. 4C, there may be a gate valve (which may be a first reaction chamber third gate valve) coupling first reaction chamber 110 and fourth transfer chamber 240C (and/or first reaction chamber 110 and fourth transfer chamber 240C may be coupled), such that fourth transfer tool 243C may transfer a substrate in or out of first reaction chamber 110 (e.g., to transfer a substrate between first reaction chamber 110 and fourth transfer chamber 240C (e.g., to bypass second reaction chamber 120C and/or third reaction chamber 130C), and/or to transfer a substrate between first reaction chamber 110 and third reaction chamber 130C (e.g., to bypass second reaction chamber 120C and/or fourth reaction chamber 140C)). There may be a gate valve (which may be a second reaction chamber third gate valve) coupling second transfer chamber 220B and third reaction chamber 130C (and/or second transfer chamber 220B and third reaction chamber 130C may be coupled), such that second transfer tool 223B may transfer a substrate in or out of third reaction chamber 130C (e.g., to transfer a substrate between first reaction chamber 110 and third reaction chamber 130C (e.g., to bypass second reaction chamber 120C)). Accordingly, in various embodiments, a chamber in a reactor system may have three gate valves coupled thereto to provide additional substrate path options through the chambers of a reactor system (for example, to utilize less than all chambers in a reactor system for a process).

In various embodiments, gate valves may be coupled to reaction chambers and/or transfer chambers within a reactor system, and/or coupled to the surrounding walls of the reaction chambers and/or transfer chambers (or any other chambers in the reactor system). In various embodiments, gate valves may be discrete components of a reactor system, or gate valves may be comprised in the reaction chambers and/or transfer chambers (or any other chambers in the reactor system), and/or the surrounding walls thereof. In various embodiments, each reaction chamber may be comprised in a reactor (e.g., the first reaction chamber may be comprised in a first reactor, the second reaction chamber may be comprised in a second reactor, etc.). In such embodiments, each reactor may further comprise at least two gate valves coupled to the reaction chamber, and/or at least two gate valves may be coupled to the reactor, the gate valves being configured to selectively allow access to the reaction chamber. In various embodiments, the gate valves coupled to a chamber or its surrounding wall may be disposed around such a chamber at any suitable angle(s) relative to other gate valves, such as those angles discussed herein in regard to chambers being disposed relative to one another.

In various embodiments, the arrangement of chambers in a reactor system may be in any suitable configuration and/or shape. For example, the reaction chambers and transfer chambers of reactor system 400A may be arranged so that there is a space between the chambers. Similarly, for example, the reaction chambers and transfer chambers of reactor system 400B may be arranged so that there is a space between the chambers (e.g., which may be accomplished by having reaction chambers positioned at an angle between 90 and 180 relative to other reaction chambers, and by having transfer chambers positioned at an angle from 90 to 180 relative to other transfer chambers). In various embodiments, reaction chambers may be positioned at any suitable angle relative to a preceding or succeeding reaction chamber in the reactor system (with a transfer chamber therebetween), such as about 90 degrees, about 120 degrees, or about 60 degrees from one another. Similarly, in various embodiments, transfer chamber may be positioned at any suitable angle relative to a preceding or succeeding transfer chamber in the reactor system (with a reaction chamber therebetween), such as about 90 degrees, about 120 degrees, or about 60 degrees from one another). In this context, “about” means plus or minus 20 or 30 degrees. As another example, a reactor system having eight chambers and an LLC may be arranged like shown in FIG. 4C, or may be arranged with space between one or more of the chambers, such as the arrangement of chambers in reactor system 500A as shown in FIG. 5A. Reactor System 500A may comprise transfer chambers, reaction chambers, and gate valves similar to those discussed in relation to reactor system 400C shown in FIG. 4C.

Processes in accordance with this disclosure also include disposing, coupling, and/or rearranging chambers and/or gate valves of a reactor system in any suitable arrangement or configuration, and/or coupling the chambers to one another and/or respective gate valves to achieve a desired arrangement. For example, an additional reaction chamber and/or transfer chamber may be coupled to a reactor system similar to 400A to create a reactor system similar to 400B. As a further example, an additional reaction chamber and/or transfer chamber may be coupled to a reactor system similar to 400B to create a reactor system similar to 400C. In various embodiments, chambers and/or gate valves may be added to, removed from, and/or rearranged within any existing reactor system to change the arrangement or shape of the reactor system.

Benefits and other advantages have been described herein with regard to specific embodiments. Furthermore, the connecting lines shown in the various figures contained herein are intended to represent exemplary functional relationships and/or physical couplings between the various elements. It should be noted that many alternative or additional functional relationships or physical connections may be present in a practical system. However, the benefits, advantages, solutions to problems, and any elements that may cause any benefit, advantage, or solution to occur or become more pronounced are not to be construed as critical, required, or essential features or elements of the disclosure. The scope of the disclosure is accordingly to be limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

Systems, methods and apparatus are provided herein. In the detailed description herein, references to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

Furthermore, no element, component, or method step in the present disclosure is intended to be dedicated to the public regardless of whether the element, component, or method step is explicitly recited in the claims. No claim element herein is to be construed under the provisions of 35 U.S.C. 112(f), unless the element is expressly recited using the phrase “means for.” As used herein, two or more components being “coupled” may mean a physical, mechanical, fluid, and/or electrical coupling, as may be dictated by the respective context. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A reactor system, comprising:
a first reaction chamber;
a first reaction chamber first gate valve coupled to the first reaction chamber and configured to allow transferring a substrate at least one of into or out of the first reaction chamber;
a first transfer chamber, wherein the first transfer chamber is in fluid communication with the first reaction chamber via the first reaction chamber first gate valve in response to the first reaction chamber first gate valve being opened, wherein the reactor system is configured to allow transfer of the substrate between the first reaction chamber and the first transfer chamber through the opened first reaction chamber first gate valve;
a first reaction chamber second gate valve coupled to the first reaction chamber and configured to allow transferring a substrate at least one of into or out of the first reaction chamber; and
a second transfer chamber in fluid communication with the first reaction chamber via the first reaction chamber second gate valve in response to the first reaction chamber second gate valve being opened, wherein the reactor system is configured to allow transfer of the substrate between the first reaction chamber and the second transfer chamber through the opened first reaction chamber second gate valve.

2. The reactor system of claim 1, wherein the first transfer chamber and the second transfer chamber are on opposite sides of the first reaction chamber.

3. The reactor system of claim 1, wherein the first transfer chamber and the second transfer chamber are disposed at an angle of less than 180 degrees with respect to an axis through the first reaction chamber.

4. The reactor system of claim 1, further comprising:
a second reaction chamber; and
a second reaction chamber first gate valve coupled to the second reaction chamber and configured to allow transferring the substrate at least one of into or out of the second reaction chamber,
wherein the second reaction chamber is in fluid communication with the second transfer chamber via the second reaction chamber first gate valve in response to the second reaction chamber first gate valve being opened.

5. The reactor system of claim 4, further comprising a second reaction chamber second gate valve coupled to the second reaction chamber, wherein the second reaction chamber is in fluid communication with the first transfer chamber via the second reaction chamber second gate valve in response to the second reaction chamber second gate valve being opened.

6. The reactor system of claim 4, further comprising:
a third transfer chamber; and
a second reaction chamber second gate valve coupled to the second reaction chamber,
wherein the second reaction chamber is in fluid communication with the third transfer chamber via the second reaction chamber second gate valve in response to the second reaction chamber second gate valve being opened.

7. The reactor system of claim 6, further comprising:
a third reaction chamber; and
a third reaction chamber first gate valve coupled to the third reaction chamber and configured to allow transferring the substrate at least one of into or out of the third reaction chamber,
wherein the third reaction chamber is in fluid communication with the third transfer chamber via the third reaction chamber first gate valve in response to the third reaction chamber first gate valve being opened.

8. The reactor system of claim 7, further comprising a third reaction chamber second gate valve coupled to the third reaction chamber, wherein the third reaction chamber is in fluid communication with at least one of the first transfer chamber or the second transfer chamber via the third reaction chamber second gate valve in response to the third reaction chamber second gate valve being opened.

9. The reactor system of claim 8, further comprising:
a fourth transfer chamber; and
a third reaction chamber third gate valve coupled to the third reaction chamber,
wherein the third reaction chamber is in fluid communication with the fourth transfer chamber via the third reaction chamber third gate valve in response to the third reaction chamber third gate valve being opened.

10. The reactor system of claim 7, further comprising:
a fourth transfer chamber; and
a third reaction chamber second gate valve coupled to the third reaction chamber,
wherein the third reaction chamber is in fluid communication with the fourth transfer chamber via the third reaction chamber second gate valve in response to the third reaction chamber second gate valve being opened.

11. The reactor system of claim 10, further comprising a first reaction chamber third gate valve coupled to the first reaction chamber, wherein the fourth transfer chamber is in fluid communication with the first reaction chamber via the first reaction chamber third gate valve in response to the first reaction chamber third gate valve being opened.

12. The reactor system of claim 10, further comprising:
a fourth reaction chamber; and
a fourth reaction chamber first gate valve coupled to the fourth reaction chamber and configured to allow transferring the substrate at least one of into or out of the fourth reaction chamber,
wherein the fourth reaction chamber is in fluid communication with the fourth transfer chamber via the fourth reaction chamber first gate valve in response to the fourth reaction chamber first gate valve being opened.

13. The reactor system of claim 12, further comprising a fourth reaction chamber second gate valve coupled to the fourth reaction chamber, wherein the fourth reaction chamber is in fluid communication with the first transfer chamber via the fourth reaction chamber second gate valve in response to the fourth reaction chamber second gate valve being opened.

14. A reactor system, comprising:
a plurality of reaction chambers;
a plurality of transfer chambers; and
at least two gate valves coupled to each reaction chamber of the plurality of reaction chambers, wherein a first gate valve of the at least two gate valves fluidly couples a first respective reaction chamber of the plurality of reaction chambers to a first transfer chamber of the plurality of transfer chambers when opened, and wherein a second gate valve of the at least two gate valves fluidly couples the first respective reaction chamber to a second transfer chamber of the plurality of transfer chambers when opened.

15. The reactor system of claim 14, wherein each of the plurality of transfer chambers comprises a transfer tool, wherein each transfer tool is configured to transfer a substrate at least one of into or out of a maximum of two of the plurality of reaction chambers.

16. A method, comprising:
transferring a first substrate to a first reaction chamber through a first reaction chamber first gate valve coupled to the first reaction chamber, via a first transfer tool comprised in a first transfer chamber, wherein the first reaction chamber and the first transfer chamber are in fluid communication in response to the first reaction chamber first gate valve being opened;
transferring the first substrate from the first reaction chamber through a first reaction chamber second gate valve coupled to the first reaction chamber, via a second transfer tool comprised in a second transfer chamber, wherein the second transfer chamber is in fluid communication with the first reaction chamber in response to the first reaction chamber second gate valve being opened;
transferring, via the second transfer tool, the substrate to a second reaction chamber through a second reaction chamber first gate valve coupled to the second reaction chamber, wherein the second reaction chamber is in fluid communication with the second transfer chamber in response to the second reaction chamber first gate valve being opened; and
transferring the substrate from the second reaction chamber.

17. The method of claim 16, wherein the transferring the substrate from the second reaction chamber is completed via the first transfer tool through a second reaction chamber second gate valve coupled to the second reaction chamber, wherein the second reaction chamber and the first transfer chamber are in fluid communication in response to the second reaction chamber second gate valve being opened.

18. The method of claim 17, further comprising:
applying a first material to the substrate in the first reaction chamber for a first duration before the transferring the substrate from the first reaction chamber; and
applying a second material to the substrate in the second reaction chamber for a second duration before the transferring the substrate from the second reaction chamber, wherein the first duration and the second duration are the same.

19. The method of claim 16, further comprising:
applying a first material to the substrate in the first reaction chamber for a first duration before the transferring the substrate from the first reaction chamber;
applying a second material to the substrate in the second reaction chamber for a second duration before the transferring the substrate from the second reaction chamber, wherein the transferring the substrate from the second reaction chamber is completed via a third transfer tool comprised in a third transfer chamber and through a second reaction chamber second gate valve coupled to the second reaction chamber, wherein the second reaction chamber and the third transfer chamber are in fluid communication in response to the second reaction chamber second gate valve being opened;
transferring, via the third transfer tool, the substrate to a third reaction chamber through a third reaction chamber first gate valve coupled to the third reaction chamber, wherein the third reaction chamber is in fluid communication with the third transfer chamber in response to the third reaction chamber first gate valve being opened; and
applying a third material to the substrate in the third reaction chamber for a third duration.

20. The method of claim 19, wherein the second material and the third material are the same, and wherein the first duration, the second duration, and the third duration are the same.
